(19) United States
(12) Patent Application Publication
(10) Pub. No.: US 2026/0093888 A1
(43) Pub. Date: Apr. 2, 2026

(54) INTEGRATED CIRCUITS EMPLOYING PROGRAMMABLE LOGIC CELL CIRCUITS TO OVERCOME ERRORS TO AVOID A RE-SPIN AND RELATED METHODS

(71) Applicant: QUALCOMM Incorporated, San Diego, CA (US)

(72) Inventors: Vardhana Mruthyunjaya, Mangalore (IN); Vasista Ati, Bangalore (IN); Kota Subba Rao Sajja, Bengaluru (IN); Ashish Mishra, Bhubaneswar (IN)

(21) Appl. No.: 18/903,100

(22) Filed: Oct. 1, 2024

(51) Int. Cl. G06F 30/343

(52) U.S. Cl. CPC G06F 30/343

(57) ABSTRACT

An integrated circuit (IC) employs programmable logic cell (PLC) circuits integrated with cell logic circuits in a logic block and a PLC controller that programs the PLC circuits to modify the logic function if a bug is found therein to reduce or avoid the need for a re-spin. The PLC circuits include logic circuits providing various logic operations, and the interconnection of these logic circuits may be modified based on PLC program data received from the PLC controller to change the logic function. The PLC circuits in the logic block may be connected in series, and the PLC program data may be received in each of the PLC circuits in a bitstream shifted through shift registers in the PLC circuits. The IC may include programmable logic devices and programmable switch matrices to provide logic functions and signal rerouting to overcome errors in signals entering or leaving the logic block.

### TECHNICAL FIELD

The technology of the disclosure relates generally to fabricating integrated circuits (ICs) that operate with their full design capabilities and, more particularly, to resolving logic problems found in an IC after fabrication.

### BACKGROUND

An integrated circuit (IC) (e.g., on a chip or die) may include millions of transistors and other circuit components arranged in a precise layout on the surface of a semiconductor substrate. The transistors and other components are interconnected with each other and to external contacts by interconnects (e.g., wires and vias) formed in metal layers on top of the transistors. The layout of the transistors and other components and details of the routing of interconnects in the metal layers depends on the functions to be provided on the IC as well as other considerations, such as space limitations, circuit timing, capacitance, heat distribution, signal noise, fabrication tolerances, etc. The IC design, including all the layout and routing details, is specified in data files that an IC designer can provide to an IC manufacturer that fabricates ICs based on the IC design in the data files. Even when IC designers take great care in the preparation of the data files, which may include functional simulations, design checks, timing analysis, and power distribution analysis, for example, there still may be one or more problems with an IC when it is fabricated (e.g., manufactured). These problems can cause the IC to have limited, if any, commercial usefulness, and in many cases, the only way to correct these problems to produce a desirable product is to fix the IC design, generate new data files, and “re-spin” (i.e., refabricate) the IC at the expense of the IC designers.

### SUMMARY

Aspects disclosed in the detailed description include integrated circuits (ICs) employing programmable logic cell (PLC) circuits to overcome logic errors to avoid a re-spin. Methods of overcoming logic errors in an IC to avoid a re-spin are also disclosed. IC fabrication includes forming circuit components (e.g., transistors) and metal interconnects on the surface of a semiconductor wafer according to specifications of an IC design described in electronic data files by an IC designer. In some instances, logic errors (bugs) that are present in the original design are not found until the IC design is fabricated, and at that point, the logic errors may be uncorrectable. Depending on the severity of such errors, the IC designer may be forced to have the IC design corrected and the IC fabricated again, which is referred to as a “re-spin,” after correcting the error.

An exemplary IC, as disclosed herein, employs PLC circuits integrated with cell logic circuits (e.g., which may be known as standard cell logic circuits) in a logic block and a PLC controller that can reprogram the PLC circuits to change the logic function of the logic block if a bug is found therein to reduce or avoid the need for a re-spin. The PLC circuits may include logic circuits providing various logic operations, and the interconnection of these logic circuits may be modified based on PLC program data received from the PLC controller to change the logic function. In some examples, the PLC circuits in the logic block may be connected in series, and the PLC program data may be received in each of the PLC circuits in a bitstream shifted through shift registers in the PLC circuits. In some examples, the IC may include programmable logic devices (PLDs) and programmable switch matrices (PSMs) outside the logic block to provide additional functions and signal rerouting to overcome errors in signals entering or leaving the logic block.

In this regard, in one aspect, an IC is disclosed. The IC includes a first logic block, comprising a first plurality of cell logic circuits and a first plurality of PLC circuits integrated with the first plurality of cell logic circuits, each configured to provide a configurable logic function. The IC also includes a PLC controller, wherein each PLC circuit of the first plurality of PLC circuits comprises a plurality of logic circuits configurable to provide a plurality of logic functions, and the PLC controller is configured to provide PLC program data to each of the first plurality of PLC circuits to configure the first plurality of PLC circuits to provide a first logic block function based on the PLC program data.

In this regard, in one aspect, a logic circuit is disclosed. The logic circuit includes a plurality of cell logic circuits configured to provide logic functions; and a plurality of PLC circuits integrated with the plurality of cell logic circuits. Each PLC circuit on the logic circuit comprising a shift register configured to receive PLC program data and a plurality of logic circuits configured to provide a logic function dependent on the PLC program data wherein the shift registers of the plurality of PLC circuits are coupled in series to receive the PLC program data in a serial bitstream.

In this regard, in one aspect, a method of overcoming errors in an IC is disclosed. The method includes integrating a first plurality of PLC circuits and a first plurality of cell logic circuits in a first logic block in an IC design of an IC, fabricating an IC based on the IC design, identifying, in the IC, of the first logic block, providing PLC program data to a PLC controller on the IC; and transmitting, by the PLC controller, the PLC program data to the first plurality of PLC circuits to program the at least one modification in the first plurality of PLC circuits.

### BRIEF DESCRIPTION OF THE DRAWINGS

FIG. 1A is a block diagram of an exemplary integrated circuit (IC), including a secure processor, a programmable logic circuit (PLC) controller, and a logic block, including PLC circuits integrated with cell logic circuits to reconfigure a logic function of the logic block;

FIG. 1B is a block diagram of the logic circuits in the PLC circuits in FIG. 1A, including various logic operations for providing a configurable logic function based on PLC program data received in a shift register;

FIG. 2 is a block diagram of another exemplary IC including multiple logic blocks, including PLC circuits, as well as programmable logic devices (PLDs), programmable switch matrices (PSMs), a secure processor, and controllers for programming the PLCs, PLDs, and PSMs to provide configurability of the logic functions internal and external to the logic blocks to avoid a re-spin;

FIG. 3 is a block diagram of an exemplary processor-based system that can include ICs in which logic blocks may include cell logic circuits integrated with programmable logic cell (PLC) circuits that can be programmed to modify a logic block function in case an error is found in the ICs, such as the ICs in FIGS. 1A and 2;

FIG. 4 is a flow chart of an exemplary process of overcoming errors in an IC as disclosed herein and illustrated in FIGS. 1A and 2 to avoid a re-spin;

FIG. 5 is a flowchart of an exemplary process of providing program data for reconfiguring a logic block in a fabricated IC;

FIG. 6 is a block diagram of an exemplary wireless communication device that includes radio-frequency (RF) components that can include ICs in which logic blocks may include cell logic circuits integrated with PLC circuits that can be programmed to modify a logic block function in case an error is found in the ICs, such as the ICs in FIGS. 1A and 2; and

FIG. 7 is a block diagram of an exemplary processor-based system that can include ICs in which logic blocks may include cell logic circuits integrated with PLC circuits that can be programmed to modify a logic block function in case an error is found in the ICs, such as the ICs in FIGS. 1A and 2.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include integrated circuits (ICs) employing programmable logic cell (PLC) circuits to overcome logic errors to avoid a re-spin. Methods of overcoming logic errors in an IC to avoid a re-spin are also disclosed. IC fabrication includes forming circuit components (e.g., transistors) and metal interconnects on the surface of a semiconductor wafer according to specifications of an IC design described in electronic data files by an IC designer. In some instances, logic errors (bugs) that are present in the original design are not found until the IC design is fabricated, and at that point, the logic errors may be uncorrectable. Depending on the severity of such errors, the IC designer may be forced to have the IC design corrected and the IC fabricated again, which is referred to as a “re-spin,” after correcting the error.

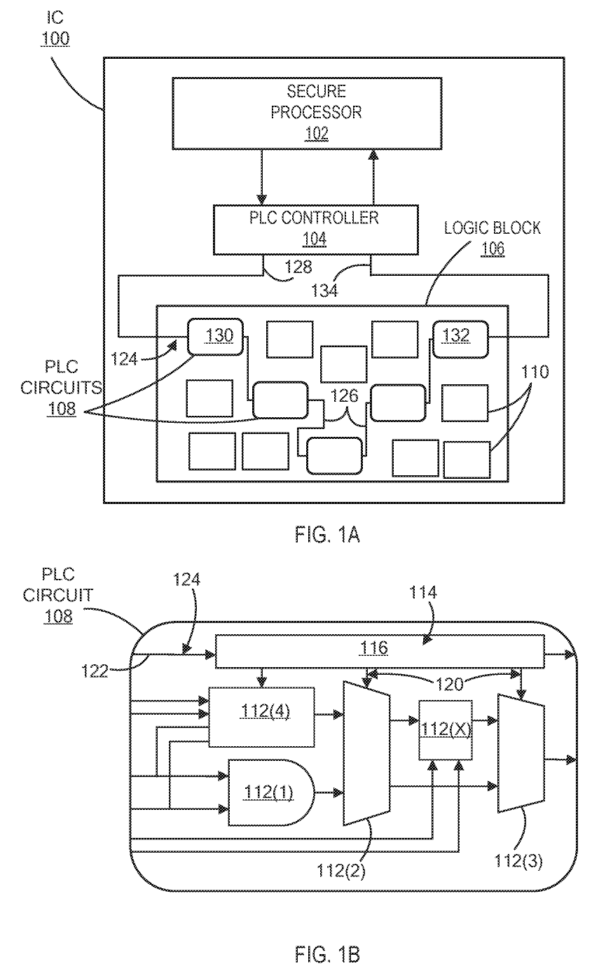

FIG. 1A is a block diagram of an exemplary IC 100, including a secure processor 102, a PLC controller 104, and a logic block 106. The logic block 106 includes PLC circuits 108 integrated with cell logic circuits 110 and may be employed to reconfigure a logic block function of the logic block 106 to avoid the need for a re-spin in the event of a logic error being found in the logic block 106 after the IC 100 is fabricated. The cell logic circuits 110, which may be known as “standard cell logic circuits,” include cell circuits that are pre-designed with a specific layout in multiple layers to form circuits, and are available to be selected from a cell logic circuit library during a design of an IC chip and laid out in a semiconductor die design. The cell logic circuits typically include both a P-type and N-type diffusion region in which P-type and N-type transistors are formed to form a logic circuit(s). The cell logic circuits are also designed such that they can be densely tiled together in a semiconductor die. The cell logic circuit library may be a standard cell logic circuit from a standard cell circuit library provided by a fabrication vendor. Some of the logic operators in the logic block 106 are, in an exemplary aspect, synthesized with PLC circuits 108, which incorporate configurability into the design in case an error is found in the fabricated IC 100.

In this context, the term “logic block” refers to digital logic circuits (not shown), including transistors that are interconnected to provide binary logical operations or functions and may include binary logic functions or operators (e.g., AND, OR etc.) and binary data storage elements (e.g., flip-flops and/or registers) that are triggered to change state in response to a system clock signal. The logic block 106 may provide any logic block function.

In some cases, ICs such as the IC 100 include many logic blocks that can operate independently or cooperatively in groups to provide the desired functions of the IC 100. An IC designer may determine which logic operators are needed for each logic block in an IC and how to interconnect them to provide a desired logic block function. A logic block design may originally be represented in a register transfer language (RTL), for example, before physical details are incorporated. Some logic blocks providing common or well-known functions may be purchased from another designer. Alternatively, an IC designer may reuse logic blocks used in a previous IC design. Previously used and purchased logic blocks have already been proven to be reliable and are much less likely than new custom-designed logic blocks to have bugs. The proven logic blocks may be used together with newly designed logic blocks that provide a new function or provide a previous function to be used in a different design for better performance, increased functionality, or fewer logic circuits (e.g., reduced power and area), as an improvement over a previous IC design, for example. Once an IC is fabricated, it is unlikely that bugs will be found in the proven logic blocks, but it is not uncommon to find problems with more recently developed logic blocks.

In this regard, in an exemplary aspect, the logic block 106 includes PLC circuits 108 integrated with cell logic circuits 110. While the logic operators of a conventional logic block may be synthesized entirely with cell logic circuits from a cell logic circuit library provided by a fabrication vendor, some of the logic operators in the logic block 106 are, in an exemplary aspect, synthesized with PLC circuits 108, which incorporate configurability into the design in case an error is found in the fabricated IC 100. A number of the PLC circuits 108 employed in the logic block 106 is design dependent, and there may be a tradeoff between increased configurability and increased area because the PLC circuits 108 may include more transistor circuits than the cell logic circuits 110, as shown in FIG. 1B.

FIG. 1B is a block diagram of the PLC circuits 108 in FIG. 1A, including logic circuits 112(1)-112(X). The logic circuits 112(1)-112(X) include various logic operators that can be configured to control a logic function based on PLC program data 114 received in a shift register 116 in the PLC circuit 108. In this example, the logic circuit 112(1) in FIG. 1B is a two-input binary AND circuit, the logic circuits 112(2) and 112(3) are multiplexers or selectors, the logic circuit 112(4) is a decoder, and the logic circuit 112(X) (where X=5 in this example) is a storage circuit (e.g., register or flip-flop). Controlling the logic function based on PLC program data 114 may include providing inputs to some or all of the logic circuits 112(1)-112(X) that will affect their outputs and selecting outputs of certain logic circuits to be used to produce a desired logic function. It may also be possible to reroute some signals in the PLC circuit 108. In this manner, the PLC circuit 108 is a configurable logic circuit that may be configured to provide a plurality of operations that can include, for example, an AND operator, an OR operator, a multiplexer, a decoder, a register, or combinations of these operators. In some examples, a different set of logic operators or functions may be included and combined in the PLC circuit 108.

The PLC circuit 108 may be employed to provide any one of several different logic functions, and it should be recognized that the PLC circuit 108 is not limited to the number and types of the logic circuits 112(1)-112(X). The logic circuits 112(1)-112(X) may be controlled and/or interconnected based on the PLC program data 114 in the shift register 116. The shift register 116 stores the PLC program data 114 as a multi-bit binary value that may be used to control inputs 120 to the logic circuits 112(1)-112(X). In addition or alternatively, though not shown in FIG. 1B, the PLC program data 114 may be employed to selectively route output signals of one or more of the logic circuits 112(1)-112(X) to be input signals of other ones of the logic circuits 112(1)-112(X) to produce the desired function.

The shift register 116 may receive the PLC program data 114 in a serial bitstream 124 that is received one bit per cycle at the input 122 and is shifted through the shift register 116 over multiple cycles or periods of the system clock (not shown). Thus, the shift register 116 is configured to receive the PLC program data 114 in the serial bitstream 124, and logic circuits 112(1)-112(X) are configured to control a logic function of the PLC circuit 108 based on the PLC program data 114.

Referring back to FIG. 1A, it can be seen that the PLC circuits 108 are coupled in a series 126 of PLC circuits 108, such that the PLC program data 114 (FIG. 1B) of each of the PLC circuits 108 may be shifted through the logic block 106. Shifting the data through the PLC circuits 108 in this manner provides the PLC program data 114 to all of the PLC circuits 108 with only a small increase in the number of interconnects in the IC 100.

The PLC program data 114 is provided to the PLC circuits 108 by the PLC controller 104, which generates the bitstream 124 on an output 128. A first PLC circuit 130 in the series 126 is coupled to the output 128 of the PLC controller 104, and a last PLC circuit 132 in the series 126 is coupled to an input 134 of the PLC controller 104 to receive the serial bitstream 124. The PLC controller 104 transmits the PLC program data 114 to the PLC circuits 108 to program a modification into the PLC circuits 108. The PLC program data 114 is transmitted by shifting the serial bitstream 124 one bit position in each clock period through the series 126 (of shift registers 116) from the output 128 to the first PLC circuit 130, through the series 126 (ending with the last PLC circuit 132), and back to the input 134 in a looping fashion. In this manner, each PLC circuit 108 in the series 126 receives the PLC program data 114 from the PLC controller 104 in a serial bitstream 124 transmitted through the series 126. Returning the PLC program data 114 to the PLC controller 104 allows the correctness of the serial bitstream 124 to be confirmed and/or a current configuration of the PLC circuits 108 may be read by the PLC controller 104 under the control of the secure processor 102.

With many PLC circuits 108 coupled in series, designers may determine that it takes too many cycles to shift the PLC program data 114 through each of the PLC circuits 108 in the logic block 106. However, this process would typically be performed only when the IC 100 is powered on. In particular, in response to executing boot instructions as part of a boot routine of the IC 100, the secure processor 102 may provide the PLC program data 114 to the PLC controller 104, and the PLC controller 104 may shift the bitstream 124 through the PLC circuits 108. Thus, the PLC controller 104 may be configured to provide PLC program data 114 to each of the PLC circuits 108 to configure the PLC circuits 108 to provide a first logic block function based on the PLC program data 114.

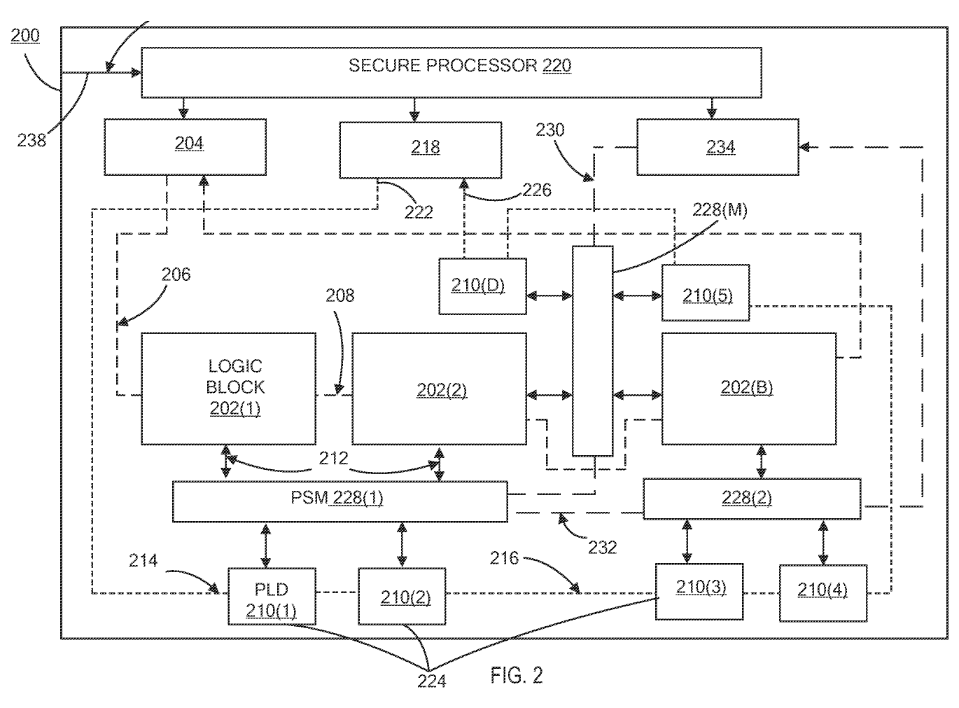

FIG. 2 is a block diagram of another example of an IC 200, including multiple logic blocks 202(1)-202(B) that may have PLC circuits 108 integrated with cell logic circuits 110, as shown in the logic block 106 in FIG. 1A. The IC 200 includes a PLC controller 204 that provides PLC program data 206 in a first bitstream 208 to PLCs (not shown) in the logic blocks 202(1)-202(B). The PLC controller 204 may correspond to the PLC controller 104 in FIG. 1. The bitstream 208 is shifted through a first series of the PLC circuits in the logic block 202(1) and through a second series of the PLC circuits in the logic block 202(2). In some examples, the serial bitstream 208 may extend through all of the logic blocks 202(1)-202(B), as shown in this example. Thus, in some examples, a first logic block 202(1) includes a first plurality of PLC circuits 108 coupled in a first series, a second logic block 202(2) includes a second plurality of PLC circuits 108 coupled in a second series, and PLC program data 206 that includes a logic modification (e.g., bug fix) for the second logic block 202(2) may be shifted into the second logic block 202(2) through the first logic block 202(1).

In some ICs, proven logic blocks may not include PLC circuits and, therefore, are not coupled in the series to receive the bitstream 208. In some examples, if the number of PLC circuits in the IC 200 exceeds a threshold, the PLCs may be divided into two or more series, and an additional (one or more) bitstream may be provided from the PLC controller 204 to shift the PLC program data 206 into respective series of the PLC circuits.

As discussed in reference to FIG. 1A, the PLC circuits 108 provide configurability within the logic block 106 and would provide the same benefit in the logic blocks 202(1)-202(B). However, some errors are not contained within a single logic block and may require additional circuitry and/or changes to an interface between logic blocks. In this regard, the IC 200 also includes programmable logic devices (PLDs) 210(1)-210(D) external to the logic blocks 202(1)-202(B) to provide additional configurable logic circuits that may be employed in case of a need for a functional change/correction of signals 212 communicated between the logic blocks 202(1)-202(B) or when the PLCs within one of the logic blocks 202(1)-202(B) is insufficient to achieve a desired corrective action. The internal circuitry of the PLDs 210(1)-210(D) may include any number of logic operators/circuits configurable according to PLD program data 214 received in shift registers, which are not shown in FIG. 2 but are similar to the shift register 116 in FIG. 1B. Since the PLDs 210(1)-210(D) may generally correspond to the PLC circuits 108 in FIG. 1B, but with potentially larger functional capacity, separate illustrations of specific internal features of the PLDs 210(1)-210(D) are not included.

The PLDs 210(1)-210(D) are configured to provide a programmable logic function based on the PLD program data 214 received from a PLD controller 218 in a serial bitstream 216. The PLD controller 218 provides the PLD program data 214 to the PLDs 210(1)-210(D) in the serial bitstream 216. The PLD controller 218 is coupled to a secure processor 220 and receives the PLD program data 214 from the secure processor 220. In a manner similar to the operation of the PLC controller 104 described with reference to FIG. 1A, the PLD controller 218 may receive the PLD program data 214 from the secure processor 220 in response to, for example, execution of a boot instructions executed in the secure processor 220. The PLD controller 218 provides the bitstream 216 on an output 222. The PLDs 210(1)-210(D) may be coupled in a series 224 as a loop, allowing the PLD controller 218 to shift the bitstream 216 through all of the PLDs 210(1)-210(D) and back to an input 226 of the PLD controller 218 over multiple clock periods.

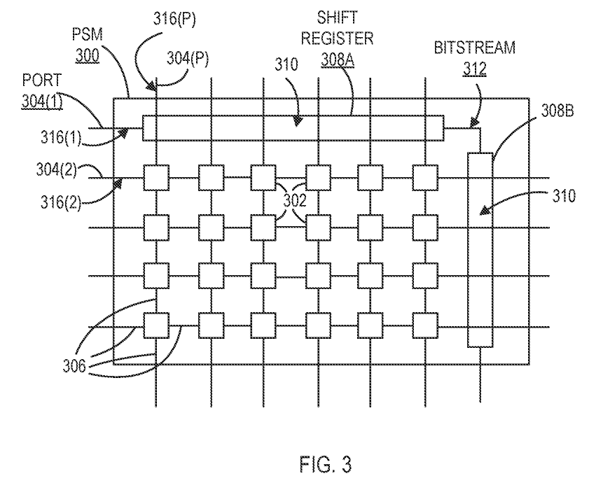

The IC 200 also includes programmable switch matrices (PSMs) 228(1)-228(M) coupled between the PLDs 210(1)-210(D), and the logic blocks 202(1)-202(B). The PSMs 228(1)-228(M) may selectively route logic signals 212 (e.g., input signals and output signals) communicated between the logic blocks 202(1)-202(B). An example of a PSM 300, which may be any of the PSMs 228(1)-228(M), is shown in detail in FIG. 3. The PSM 300 in this example includes a two-dimensional array of switches 302 coupled to ports 304(1)-304(P). Each of the switches 302 is coupled to four interconnects (e.g., wires) 306 and may be configured to couple any two of the four interconnects 306 to each other. The PSM 300 includes shift registers 308A and 308B, which may be implemented separately or as a single continuous shift register to receive PSM program data 310. The PSM program data 310 may be shifted into the shift registers 308A and 308B in a bitstream 312. With continued reference to FIG. 2 and FIG. 3, the PSM program data 310 in FIG. 3 corresponds to PSM program data 230 in FIG. 2, and the bitstream 312 in FIG. 3 may be a bitstream 232 provided by a PSM controller 234 coupled to the secure processor 220 as shown in FIG. 2. Based on the PSM program data 310, signals 316(1)-316(P) on any of the ports 304(1)-304(P) may be routed to any of the other ports 304(1)-304(P), providing the capability for the PSMs 228(1)-228(M) in FIG. 2 to selectively reroute the signals 212 to change the function of the IC 200.

As shown in FIG. 2, the PSMs 228(1)-228(M) may be coupled in series to receive the PSM program data 230 in the bitstream 232. The PSM controller 234 is configured to provide the PSM program data 230 to the PSMs 228(1)-228(M) in the serial bitstream 232. The PSMs 228(1)-228(M) may be configured to selectively route logic signals 212 generated in the logic blocks 202(1)-202(B) into one or more other logic blocks 202(1)-202(B) and/or to/from the PLDs 210(1)-210(D) based on PSM program data 230. For example, the PSMs 228(1)-228(M) may be coupled to some or all of the input and/or output signals 212 of the logic blocks 202(1)-202(B) and may route any output signal(s) 212 from a first one of the logic blocks 202(1)-202(B) directly to any other logic block 202(1)-202(B). Alternatively, the PSMs 228(1)-228(M) may selectively route signals to one of the PLDs 210(1)-210(D) to perform additional processing and may couple signals 212 generated in the PLDs 210(1)-210(D) back to any one of the logic blocks 202(1)-202(B), thereby modifying/correcting internal logic function of the IC 200 to overcome a design error and avoid the need for a re-spin of the IC 200.

The PSMs 228(1) and 228(2) in FIG. 2 are coupled between the logic blocks 202(1)-202(B) and corresponding PLDs 210(1)-210(D), where they may route signals of the logic blocks 202(1)-202(B) to the PLDs 210(1)-210(D), to provide additional logic functions to the logic blocks 202(1)-202(B). In contrast, the PSM 228(M) (where M=3 in this example) is coupled directly to each of the logic blocks 202(2) and 202(B) in addition to being coupled to PLDs 210(1)-210(D). In this example, the PSM 228(M) may reroute signals 212 output from the logic blocks 202(2) and 202(B) to different inputs of the other one of the logic blocks 202(M) and 202(2) to implement a change in function or connectivity that does not require additional logic circuits. Other configurations of the PSMs 228(1)-228(M) among the logic blocks 202(1)-202(B) and PLDs 210(1)-210(D) are available depending on design considerations.

In this example, the secure processor 220 receives the PLC program data 206, the PLD program data 214, and the PSM program data 230 in serial data 236 on an input 238 of the IC 200. The serial bitstreams 208, 216, and 232 may be received sequentially in one continuous transmission of the serial data 236 or in independent transmissions of the serial data 236. The serial bitstreams 208, 216, and 232 may also be interleaved in any manner in the serial data 236. Alternatively, the secure processor 220 may receive the PLC program data 206, the PLD program data 214, and the PSM program data 230 in another manner, such as over a parallel interface. The serial data 236 may be divided internally by the secure processor 220 to create each of the bitstreams 208, 216, and 232. Although the PLC controller 204, the PLD controller 218, and the PSM controller 234 in FIG. 2 may provide the PLC program data 206, the PLD program data 214, and the PSM program data 230 by serial bitstreams in this example to minimize interconnect congestion in the metal layers of the IC 200, the IC 200 is not limited in this regard. The PLC program data 206, the PLD program data 214, and the PSM program data 230 may be transmitted or distributed to the PLC circuits 108, the PLDs 210(1)-210(D), and the PSMs 228(1)-228(M) by another means such as a system bus, shared parallel interfaces, dedicated communications interfaces, or other appropriate means.

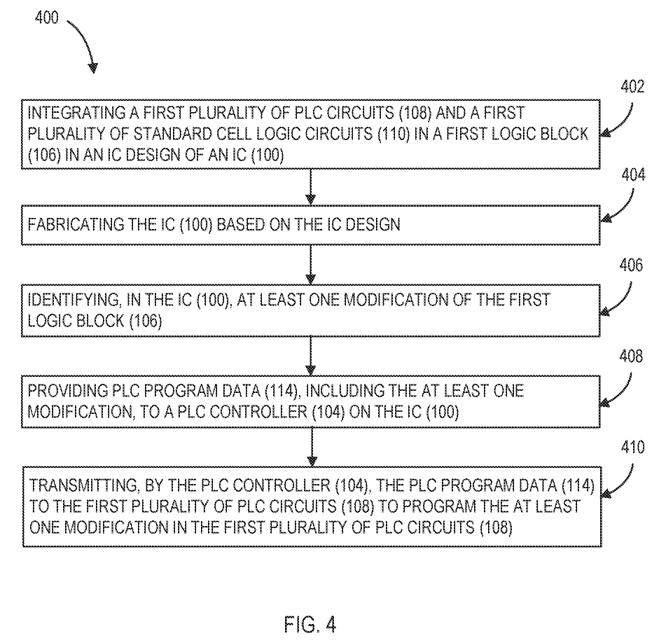

FIG. 4 is a flowchart of a method 400 to overcome errors in an IC, such as the IC 100 and the IC 200 in FIGS. 1A and 2, in which logic blocks include PLC circuits 108. The method 400 includes integrating a first plurality of PLC circuits 108 and a first plurality of cell logic circuits 110 in a first logic block 106 in an IC design of an IC 100 (block 402) and fabricating the IC 100 based on the IC design (block 404). Integrating PLC circuits 108 with cell logic circuits 110 in a design of a logic block 106 may include identifying certain logic operators in the logic block 106 to be replaced by PLC circuits 108 specially designed for this purpose or selected from a library of cell logic circuits including programmable cell circuits while the remaining logic operators may be instantiated as cell logic circuits from a cell logic circuit library in the process of synthesizing the logic operators as physical circuits. As discussed above, the IC design may be provided to an IC fabricator in electronic data files that specify the physical details of the IC 100. The method 400 further includes identifying, in the IC 100, at least one modification of the first logic block 106 (block 406). The at least one modification may be a correction or fix for a bug or logic error found in the IC 100 once it has been fabricated. The bug may manifest as a logic or functional failure found during testing of the IC 100. The bug may actually be a logic error in the design, or the bug may be due to other factors, such as excessive signal delay, which can have many causes. In some examples, a bug may only be apparent at or above a certain frequency of a clock signal provided to the logic block 106 in the IC 100.

Rather than being forced to refabricate (re-spin) the IC 100, the method 400 includes providing PLC program data 114, including the at least one modification to a PLC controller 104 on the IC 100 (block 408) and transmitting by the PLC controller 104, the PLC program data 114 to the first plurality of PLC circuits 108 to program the at least one modification in the first plurality of PLC circuits 108 (block 410).

In the method 400 of the IC 100, each PLC circuit 108 of the first plurality of PLC circuits includes a shift register 116 configured to receive the PLC program data 114 and logic circuits configured to control a logic function of the PLC circuit 108 based on the PLC program data 114. The method 400 further includes shifting a serial bitstream 124 comprising the PLC program data 114 from the PLC controller 104 to the shift register 116

The first plurality of PLC circuits 108 in a first logic block 106, 202(1) are coupled in a first series of PLC circuits 108, and the IC 100 includes a second logic block 202(2) comprising a second plurality of PLC circuits 108 coupled in a second series of PLC circuits 108. The method 400 further includes shifting PLC program data 114, 206 comprising a logic modification of the second logic block 202(2) into the second logic block 202(2) through the first logic block 202(1).

The IC 200 further comprises a PLD 210(1) and a PSM 228(1) coupled between the first logic block 202(1) and the PLD 210(1). The IC 200 also includes a PLD controller 218 and a PSM controller 234. In some examples, the method 400 may further include providing, by the PLD controller 218, PLD program data 214 to the PLD 210(1) to implement a logic modification and providing, by the PSM controller 234, PSM program data 230 to the PSM 228(1) to configure the PSM 228(1) to selectively route logic signals between the first logic block 202(1) and the PLD 210(1).

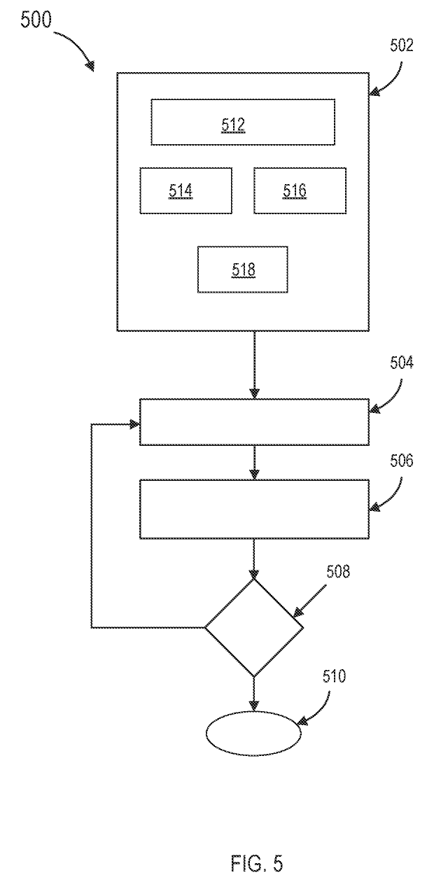

FIG. 5 is a flowchart of a process 500 for providing program data for reconfiguring a logic block in a fabricated IC. In the examples above, the process 500 may be employed to generate the serial bitstream 236 including the PLC program data 206, the PLD program data 214, and the PSM program data 230 to configure and reconfigure the logic block 106 of FIG. 1. The process 500 includes identifying the IC 200 shown in FIG. 2 and the features therein to be configured (block 502). Identifying the IC 200 may include identifying a chip family/device identifier 512 of the IC 200 and determining which of a PLC ID 514, a PLD ID 516, and/or a PSM ID 518 are to be configured. Any of the PLC ID 514, PLD ID 516, and/or PSM ID 518 may be reused from one IC design to another. The identifying may be achieved through a user interface and/or a tool chain.

For example, after initially powering on the IC 200, all of the PLCs 202(1)-202(B), PLDs 210(1)-210(D), and PSMs 228(1)-228(M) are to be configured to operate according to an original design. Thus, the serial bitstream 236 may include all of the PLC program data 206, the PLD program data 214, and the PSM program data 230.

The process 500 includes preparing the serial bitstream 236 (block 504), which may include accumulating the PLC program data 206, the PLD program data 214, and the PSM program data 230 for all of the PLCs 202(1)-202(B), PLDs 210(1)-210(D), and PSMs 228(1)-228(M). As explained further below, preparing the serial bitstream 236 may include modifying one or more of the PLC program data 206, the PLD program data 214, and the PSM program data 230.

The process 500 includes loading the serial bitstream 236 including a number of binary digits (bits) corresponding to a total of all the PLC program data 206, the PLD program data 214, and the PSM program data 230, into the IC 200 (block 506). Loading the serial bitstream 236 may include shifting the bitstream one bit position in each cycle of a clock to load some or all of the bitstream into the secure processor 220. Alternatively, the PLC program data 206, the PLD program data 214, and the PSM program data 230 may be provided to the secure processor 220 in a multi-bit interface.

The process 500 includes determining (e.g., based on testing or normal operation) whether there is a bug, error, or any type of problem in the IC 200 and determining that a modification to the serial bitstream 236 is needed (block 508). Designers determine which of the PLCs 202(1)-202(B), PLDs 210(1)-210(D), and PSMs 228(1)-228(M) need to be reconfigured and how to do so, and modify a corresponding portion of the serial bitstream 236. In some examples, only the modified portion may be provided to the secure processor 220 for a logic change to the IC 200. In other examples, all of the PLC program data 206, the PLD program data 214, and the PSM program data 230, including the modified portion(s), are provided in a single serial bitstream 236. If the process 500 determines that there are no bugs, errors or problems, the process 500 ends (block 510).

ICs, including pillar bars disposed on a row of transistors and having intermediate layers with a plurality of separate metal regions to reduce stresses, may be included in processor-based devices. Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, and a vehicle component.

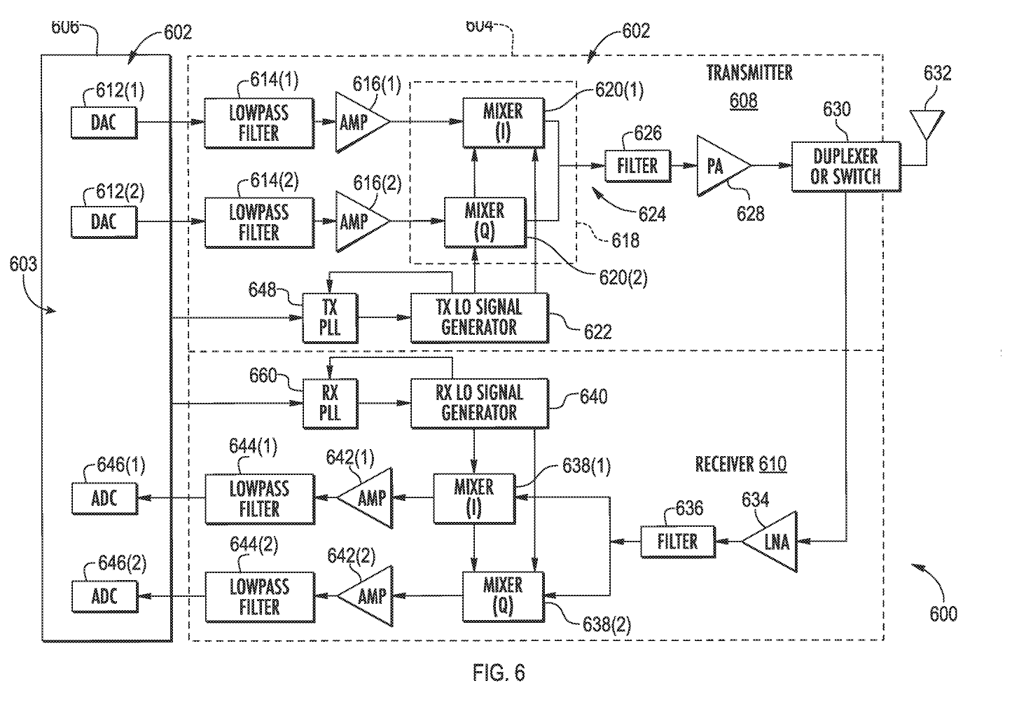

FIG. 6 illustrates an exemplary wireless communications device 600 that includes radio-frequency (RF) components formed from one or more ICs 602, wherein any of the ICs 602 may include ICs in which logic blocks may include cell logic circuits integrated with programmable logic cell (PLC) circuits 108 that can be programmed to modify a logic block function in case an error is found in the ICs, such as the ICs 100 and 200 in FIGS. 1A and 2, and may be included in processor-based devices. The wireless communications device 600 may include or be provided in any of the above-referenced devices as examples. As shown in FIG. 6, the wireless communications device 600 includes a transceiver 604 and a data processor 606. The data processor 606 may include a memory to store data and program codes. The transceiver 604 includes a transmitter 608 and a receiver 610 that support bi-directional communications. In general, the wireless communications device 600 may include any number of transmitters 608 and/or receivers 610 for any number of communication systems and frequency bands. All or a portion of the transceiver 604 may be implemented on one or more analog ICs, RF ICs (RFICs), mixed-signal ICs, etc.

The transmitter 608 or the receiver 610 may be implemented with a super-heterodyne or direct-conversion architecture. In the super-heterodyne architecture, a signal is frequency-converted between RF and baseband in multiple stages, for example, from RF to an intermediate frequency (IF) in one stage and then from IF to baseband in another stage for the receiver 610. In the direct-conversion architecture, a signal is frequency-converted between RF and baseband in one stage. The super-heterodyne and direct-conversion architectures may use different circuit blocks and/or have different requirements. In the wireless communications device 600 in FIG. 6, the transmitter 608 and the receiver 610 are implemented with the direct-conversion architecture.

In the transmit path, the data processor 606 processes data to be transmitted and provides I and Q analog output signals to the transmitter 608. In the exemplary wireless communications device 600, the data processor 606 includes digital-to-analog converters (DACs) 612(1), 612(2) for converting digital signals generated by the data processor 606 into the I and Q analog output signals (e.g., I and Q output currents) for further processing.

Within the transmitter 608, lowpass filters 614(1), 614(2) filter the I and Q analog output signals, respectively, to remove undesired signals caused by the prior digital-to-analog conversion. Amplifiers (AMPs) 616(1), 616(2) amplify the signals from the lowpass filters 614(1), 614(2), respectively, and provide I and Q baseband signals. An upconverter 618 upconverts the I and Q baseband signals with I and Q transmit (TX) local oscillator (LO) signals through mixers 620(1), 620(2) from a TX LO signal generator 622 to provide an upconverted signal 624. A filter 626 filters the upconverted signal 624 to remove undesired signals caused by the frequency up-conversion as well as noise in a receive frequency band. A power amplifier (PA) 628 amplifies the upconverted signal 624 from the filter 626 to obtain the desired output power level and provides a transmit RF signal. The transmit RF signal is routed through a duplexer or switch 630 and transmitted via an antenna 632.

In the receive path, the antenna 632 receives signals transmitted by base stations and provides a received RF signal, which is routed through the duplexer or switch 630 and provided to a low noise amplifier (LNA) 634. The duplexer or switch 630 is designed to operate with a specific receive (RX)-to-TX duplexer frequency separation, such that RX signals are isolated from TX signals. The received RF signal is amplified by the LNA 634 and filtered by a filter 636 to obtain a desired RF input signal. Down-conversion mixers 638(1), 638(2) mix the output of the filter 636 with I and Q RX LO signals (i.e., LO_I and LO_Q) from an RX LO signal generator 640 to generate I and Q baseband signals. The I and Q baseband signals are amplified by AMPs 642(1), 642(2) and further filtered by lowpass filters 644(1), 644(2) to obtain I and Q analog input signals, which are provided to the data processor 606. In this example, the data processor 606 includes analog-to-digital converters (ADCs) 646(1), 646(2) for converting the analog input signals into digital signals to be further processed by the data processor 606.

In the wireless communications device 600 of FIG. 6, the TX LO signal generator 622 generates the I and Q TX LO signals used for frequency up-conversion, while the RX LO signal generator 640 generates the I and Q RX LO signals used for frequency down-conversion. Each LO signal is a periodic signal with a particular fundamental frequency. A TX phase-locked loop (PLL) circuit 648 receives timing information from the data processor 606 and generates a control signal used to adjust the frequency and/or phase of the TX LO signals from the TX LO signal generator 622. Similarly, an RX PLL circuit 650 receives timing information from the data processor 606 and generates a control signal used to adjust the frequency and/or phase of the RX LO signals from the RX LO signal generator 640.

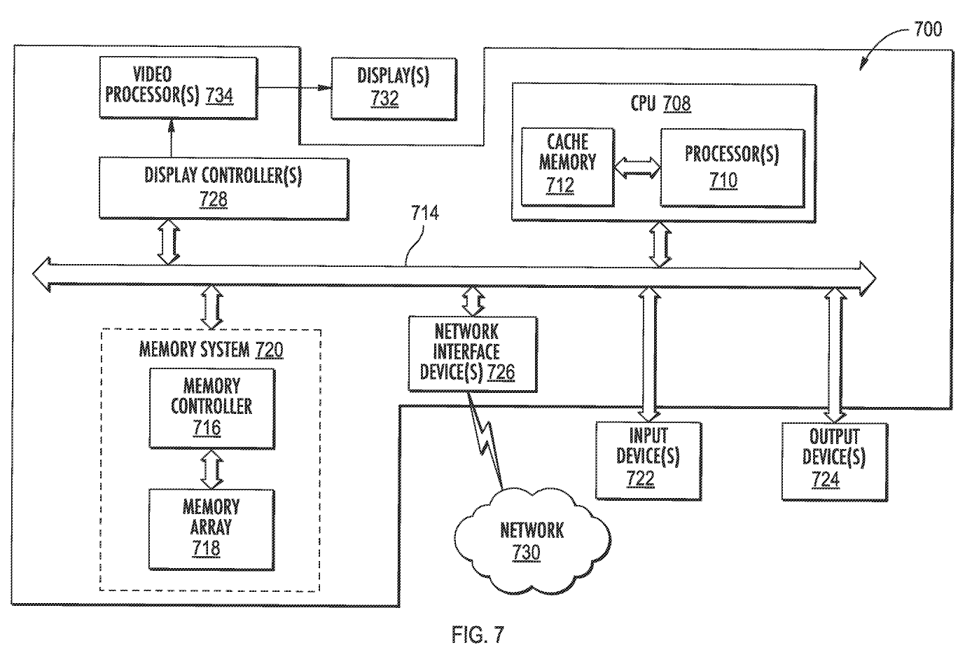

In this regard, FIG. 7 illustrates an example of a processor-based system 700 that can include ICs in which logic blocks may include cell logic circuits integrated with programmable logic cell (PLC) circuits 108 that can be programmed to modify a logic block function in case an error is found in the ICs, such as the ICs 100 and 200 in FIGS. 1A and 2. The processor-based system 700 includes a central processing unit (CPU) 708 that includes one or more processors 710, which may also be referred to as CPU cores or processor cores. The CPU 708 may have cache memory 712 coupled to the CPU 708 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716, as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow an exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processor(s) 734, which processes the information to be displayed into a format suitable for the display(s) 732. The display(s) 732 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:

1. An integrated circuit (IC) comprising: a first logic block, comprising: a first plurality of cell logic circuits; and a first plurality of programmable logic cell (PLC) circuits integrated with the first plurality of cell logic circuits and each configured to provide a configurable logic function; a PLC controller, wherein: each PLC circuit of the first plurality of PLC circuits comprises a plurality of logic circuits configurable to provide a plurality of logic functions; and the PLC controller is configured to provide PLC program data to each of the first plurality of PLC circuits to configure the first plurality of PLC circuits to provide a first logic block function based on the PLC program data.

2. The IC of clause 1, wherein: the first plurality of PLC circuits in the first logic block are coupled in a first series of PLC circuits; and each PLC circuit in the first series of PLC circuits receives the PLC program data from the PLC controller in a first serial bitstream transmitted through the first series of PLC circuits.

3. The IC of clause 2, each PLC circuit of the first plurality of PLC circuits further comprises: a shift register to receive the PLC program data in the first serial bitstream; and logic circuits configured to control a logic function of the PLC circuit based on the PLC program data.

4. The IC of clause 2 or clause 3, further comprising: a second logic block comprising cell logic circuits integrated with a second plurality of PLC circuits, wherein: the second plurality of PLC circuits is coupled in a second series of PLC circuits; and the second series of PLC circuits is coupled in series with the first series of PLC circuits to the PLC controller.

5. The IC of any of clause 1 to clause 4, further comprising: a first programmable logic device (PLD); a first programmable switch matrix (PSM) coupled between the first logic block and the first PLD; a PLD controller coupled to the secure processor; and a PSM controller coupled to the secure processor, wherein: the first PLD provides a programmable logic function based on PLD program data received from the PLD controller; and the first PSM selectively routes logic signals between the first logic block and the first PLD based on PSM program data received from the PSM controller.

6. The IC of clause 5, wherein: the PLD controller is configured to provide the PLD program data to the first PLD in a second serial bitstream; and the PSM controller is configured to provide the PSM program data to the first PSM in a third serial bitstream.

7. The IC of clause 5 or clause 6, further comprising: a second logic block comprising cell logic circuits integrated with a second plurality of PLC circuits; a second PLD; and a second PSM, wherein: the second PLD provides a second programmable logic function based on the PLD program data received from the second PLD controller; and the second PSM selectively routes logic signals between the second logic block and the second PLD based on the PSM program data received from the PSM controller.

8. The IC of clause 7, wherein: the second PLD is coupled in series with the first PLD to receive the PLD program data from the PLD controller; and the second PSM is coupled in series with the first PSM to receive the PSM program data from the PSM controller.

9. The IC of clause 7 or clause 8, further comprising a third PSM coupled between the first logic block and the second logic block.

10. The IC of clause 9, wherein the third PSM is configured to selectively route logic signals between the first logic block and the second logic block based on the PSM program data.

11. The IC of clause 9 or clause 10, wherein the third PSM is coupled in series with the first PSM and the second PSM to receive the PSM program data.

12. The IC of clause 9, further comprising a third PLD coupled to the third PSM, wherein the third PLD is coupled in series with the first PLD and the second PLD to receive the PLD program data.

13. The IC of any of clause 2 to clause 12, wherein the PLC controller is configured to provide the PLC program data to the first series of PLC circuits in response to the secure processor executing boot instructions for the IC.

14. The IC of any of clause 1 to clause 13 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; and a vehicle component.

15. A logic circuit, comprising: a plurality of cell logic circuits configured to provide logic functions; and a plurality of programmable logic cell (PLC) circuits integrated with the plurality of cell logic circuits, each PLC circuit comprising: a shift register configured to receive PLC program data; and a plurality of logic circuits configured to provide a logic function dependent on the PLC program data; wherein the shift registers of the plurality of PLC circuits are coupled in series to receive the PLC program data in a serial bitstream.

16. The logic circuit of clause 15, wherein one or more bits of the PLC program data in the shift register of each PLC circuit are provided to inputs of logic circuits in the plurality of logic circuits to control an output of the logic circuits.

17. A method of overcoming errors in an integrated circuit (IC), the method comprising: integrating a first plurality of programmable logic cell (PLC) circuits and a first plurality of cell logic circuits in a first logic block in an IC design of an IC; fabricating an IC based on the IC design; identifying, in the IC, at least one modification of the first logic block; providing PLC program data to a PLC controller on the IC; and transmitting, by the PLC controller, the PLC program data to the first plurality of PLC circuits to program the at least one modification in the first plurality of PLC circuits.

18. The method of clause 17, wherein: each PLC circuit of the first plurality of PLC circuits comprises: a shift register configured to receive the PLC program data; and logic circuits configured to control a logic function of the PLC circuit based on the PLC program data; and the method further comprises shifting a bitstream comprising the PLC program data from the PLC controller into the shift register.

19. The method of clause 17, wherein: the first plurality of PLC circuits in the first logic block are coupled in a first series of PLC circuits; the IC comprises a second logic block comprising a second plurality of PLC circuits coupled in a second series of PLC circuits; and the method further comprises shifting PLC program data comprising a logic modification of the second logic block into the second logic block through the first logic block.

20. The method of any of clause 17 to clause 19, wherein: the IC further comprises: a first programmable logic device (PLD); a first programmable switch matrix (PSM) coupled between the first logic block and the first PLD; a PLD controller; and a PSM controller; and the method further comprises: providing, by the PLD controller, a PLD program data to the first PLD to implement a third logic modification; and providing, by the PSM controller, a PSM program data to the first PSM to configure the first PSM to selectively route logic signals between the first logic block and the first PLD.

What is claimed is:

1. An integrated circuit (IC) comprising:
a first logic block, comprising:
a first plurality of cell logic circuits; and
a first plurality of programmable logic cell (PLC) circuits integrated with the first plurality of cell logic circuits and each configured to provide a configurable logic function;
a PLC controller,
wherein:
each PLC circuit of the first plurality of PLC circuits comprises a plurality of logic circuits configurable to provide a plurality of logic functions; and
the PLC controller is configured to provide PLC program data to each of the first plurality of PLC circuits to configure the first plurality of PLC circuits to provide a first logic block function based on the PLC program data.

2. The IC of claim 1, wherein:
the first plurality of PLC circuits in the first logic block are coupled in a first series of PLC circuits; and
each PLC circuit in the first series of PLC circuits receives the PLC program data from the PLC controller in a first serial bitstream transmitted through the first series of PLC circuits.

3. The IC of claim 2, each PLC circuit of the first plurality of PLC circuits further comprises:
a shift register to receive the PLC program data in the first serial bitstream; and
logic circuits configured to control a logic function of the PLC circuit based on the PLC program data.

4. The IC of claim 2, further comprising:
a second logic block comprising cell logic circuits integrated with a second plurality of PLC circuits,
wherein:
the second plurality of PLC circuits is coupled in a second series of PLC circuits; and
the second series of PLC circuits is coupled in series with the first series of PLC circuits to the PLC controller.

5. The IC of claim 1, further comprising:
a first programmable logic device (PLD);
a first programmable switch matrix (PSM) coupled between the first logic block and the first PLD;
a PLD controller coupled to the secure processor; and
a PSM controller coupled to the secure processor,
wherein:
the first PLD provides a programmable logic function based on PLD program data received from the PLD controller; and
the first PSM selectively routes logic signals between the first logic block and the first PLD based on PSM program data received from the PSM controller.

6. The IC of claim 5, wherein:
the PLD controller is configured to provide the PLD program data to the first PLD in a second serial bitstream; and
the PSM controller is configured to provide the PSM program data to the first PSM in a third serial bitstream.

7. The IC of claim 5, further comprising:
a second logic block comprising cell logic circuits integrated with a second plurality of PLC circuits;
a second PLD; and
a second PSM,
wherein:
the second PLD provides a second programmable logic function based on the PLD program data received from the second PLD controller; and
the second PSM selectively routes logic signals between the second logic block and the second PLD based on the PSM program data received from the PSM controller.

8. The IC of claim 7, wherein:
the second PLD is coupled in series with the first PLD to receive the PLD program data from the PLD controller; and
the second PSM is coupled in series with the first PSM to receive the PSM program data from the PSM controller.

9. The IC of claim 7, further comprising a third PSM coupled between the first logic block and the second logic block.

10. The IC of claim 9, wherein the third PSM is configured to selectively route logic signals between the first logic block and the second logic block based on the PSM program data.

11. The IC of claim 9, wherein the third PSM is coupled in series with the first PSM and the second PSM to receive the PSM program data.

12. The IC of claim 9, further comprising a third PLD coupled to the third PSM, wherein the third PLD is coupled in series with the first PLD and the second PLD to receive the PLD program data.

13. The IC of claim 2, wherein the PLC controller is configured to provide the PLC program data to the first series of PLC circuits in response to the secure processor executing boot instructions for the IC.

14. The IC of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; and a vehicle component.

15. A logic circuit, comprising:
a plurality of cell logic circuits configured to provide logic functions; and
a plurality of programmable logic cell (PLC) circuits integrated with the plurality of cell logic circuits, each PLC circuit comprising:
a shift register configured to receive PLC program data; and
a plurality of logic circuits configured to provide a logic function dependent on the PLC program data;
wherein the shift registers of the plurality of PLC circuits are coupled in series to receive the PLC program data in a serial bitstream.

16. The logic circuit of claim 15, wherein one or more bits of the PLC program data in the shift register of each PLC circuit are provided to inputs of logic circuits in the plurality of logic circuits to control an output of the logic circuits.

17. A method of overcoming errors in an integrated circuit (IC), the method comprising:
integrating a first plurality of programmable logic cell (PLC) circuits and a first plurality of cell logic circuits in a first logic block in an IC design of an IC;
fabricating an IC based on the IC design;
identifying, in the IC, at least one modification of the first logic block;
providing PLC program data to a PLC controller on the IC; and
transmitting, by the PLC controller, the PLC program data to the first plurality of PLC circuits to program the at least one modification in the first plurality of PLC circuits.

18. The method of claim 17, wherein:
each PLC circuit of the first plurality of PLC circuits comprises:
a shift register configured to receive the PLC program data; and
logic circuits configured to control a logic function of the PLC circuit based on the PLC program data; and
the method further comprises shifting a bitstream comprising the PLC program data from the PLC controller into the shift register.

19. The method of claim 17, wherein:
the first plurality of PLC circuits in the first logic block are coupled in a first series of PLC circuits;
the IC comprises a second logic block comprising a second plurality of PLC circuits coupled in a second series of PLC circuits; and
the method further comprises shifting PLC program data comprising a logic modification of the second logic block into the second logic block through the first logic block.

20. The method of claim 17, wherein:
the IC further comprises:
a first programmable logic device (PLD);
a first programmable switch matrix (PSM) coupled between the first logic block and the first PLD;
a PLD controller; and
a PSM controller; and
the method further comprises:
providing, by the PLD controller, a PLD program data to the first PLD to implement a third logic modification; and
providing, by the PSM controller, a PSM program data to the first PSM to configure the first PSM to selectively route logic signals between the first logic block and the first PLD.
